(19) United States
(12) Patent Application Publication
(10) Pub. No.: US 2025/0175276 A1
(43) Pub. Date: May 29, 2025

(54) SIGNAL GENERATION APPARATUS, SIGNAL GENERATION METHOD, AND COMPUTER PROGRAM

(71) Applicant: NIPPON TELEGRAPH AND TELEPHONE CORPORATION, Tokyo (JP)

(72) Inventors: Masanori NAKAMURA, Musashino-shi (JP); Hiroshi YAMAZAKI, Musashino-shi (JP); Munehiko NAGATANI, Musashino-shi (JP); Fukutaro HAMAOKA, Musashino-shi (JP); Takayuki KOBAYASHI, Musashino-shi (JP); Yutaka MIYAMOTO, Musashino-shi (JP)

(73) Assignee: NIPPON TELEGRAPH AND TELEPHONE CORPORATION, Tokyo (JP)

(21) Appl. No.: 18/841,979

(22) PCT Filed: Mar. 4, 2022
(86) PCT No.: PCT/JP2022/009432

§ 371 Date: Aug. 27, 2024

(51) Int. Cl. H04J 1/08; H03M 1/66

(52) U.S. Cl. CPC H04J 1/08; H03M 1/662

(57) ABSTRACT

A signal generation device that includes a digital signal processing unit, a plurality of sub-digital-analog conversion units that respectively converts a plurality of digital signals output from the digital signal processing unit into analog signals, and an analog multiplexer that multiplexes the analog signals output from the plurality of sub-digital-analog conversion units to generate a broadband signal, in which the digital signal processing unit includes a band division unit that divides an input signal for each frequency width of a common divisor of a Nyquist frequency of the plurality of sub-digital-analog conversion units and a clock frequency of the analog multiplexer to generate N (N is a number of divisions) divided signals, a spectrum folding unit that has the N divided signals generated by the band division unit branched on a path, and folds back the branched N divided signals on a frequency axis to obtain complex conjugation to generate N folded divided signals corresponding to the N divided signals, a filter that receives the N divided signals and the N folded divided signals as inputs and generates N composite signals, and a band combining unit that receives the N composite signals as inputs and generates a plurality of digital signals corresponding to the respective sub-digital-analog conversion units.

### TECHNICAL FIELD

The present invention relates to a signal generation device, a signal generation method, and a computer program.

### BACKGROUND ART

A high-quality high-speed signal generation technology for increasing the capacity of optical transmission has attracted attention. As such a technology, for example, a signal generation device has been proposed, which divides an input signal to be a target into a low frequency and a high frequency and pre-equalizes a divided signal and a complex conjugate signal of the divided signal by multiple input multiple output (MIMO) processing (see, for example, Patent Literature 1).

FIG. 3 is a diagram illustrating a configuration example of a conventional signal generation device 100. The signal generation device 100 includes a band division unit 611, a spectrum folding unit 612, a filter 613, a plurality of sub digital analog converters (DACs) 121 and 122, and an analog multiplexer 131. The band division unit 611 divides an input signal into a low frequency and a high frequency. The spectrum folding unit 612 generates a complex conjugate signal of a divided signal. The filter 613 receives each divided signal and each complex conjugate signal as inputs, and generates a plurality of composite signals to be transmitted to the plurality of SubDACs 121 and 122. The SubDACs 121 and 122 convert the plurality of composite signals output from the filter 613 into a plurality of analog signals. The analog multiplexer 131 receives the plurality of analog signals as inputs and generates a high-speed signal.

### CITATION LIST

### Patent Literature

Patent Literature 1: WO 2020/054173 A

### SUMMARY OF INVENTION

### Technical Problem

However, in the signal generation method by the conventional signal generation device, an interference of an alias image due to zero time hold of the SubDAC cannot be compensated under a driving condition in which aliasing occurs in an output signal of the SubDAC (for example, in a case where the SubDAC is driven at a sampling frequency at which a Nyquist frequency is smaller than an analog band of the SubDAC), and there is a problem that a frequency domain cannot be sufficiently utilized in generation of a broadband signal.

FIGS. 4 and 5 are diagrams for describing the problem in the conventional signal generation device. In FIGS. 4 and 5, the sampling frequency of the SubDAC is 126 giga sample per second (GS/s), and the frequency of a clock input to the analog multiplexer is 42 GHz. As illustrated in FIG. 4, in the case of the driving condition under which aliasing occurs in the output signal of the SubDAC, the maximum frequency is 84 GHZ, and it can be seen that the maximum frequency is limited. Therefore, the sampling frequency of the SubDAC cannot be sufficiently utilized. As illustrated in FIG. 5, in a case where aliasing exists in the SubDAC, an interference occurs in a target high-speed signal due to an alias component.

In view of the above circumstances, an object of the present invention is to provide a technique capable of generating a high-speed signal by sufficiently utilizing a frequency domain.

### Solution to Problem

One aspect of the present invention is a signal generation device including: a digital signal processing unit; a plurality of sub-digital-analog conversion units that respectively converts a plurality of digital signals output from the digital signal processing unit into analog signals; and an analog multiplexer that multiplexes the analog signals output from the plurality of sub-digital-analog conversion units to generate a broadband signal, in which the digital signal processing unit includes a band division unit that divides an input signal for each frequency width of a common divisor of a Nyquist frequency of the plurality of sub-digital-analog conversion units and a clock frequency of the analog multiplexer to generate N (N is a number of divisions) divided signals, a spectrum folding unit that has the N divided signals generated by the band division unit branched on a path, and folds back the branched N divided signals on a frequency axis to obtain complex conjugation to generate N folded divided signals corresponding to the N divided signals, a filter that receives the N divided signals and the N folded divided signals as inputs and generates N composite signals, and a band combining unit that receives the N composite signals as inputs and generates a plurality of digital signals corresponding to the respective sub-digital-analog conversion units.

One aspect of the present invention is a signal generation method including: by a digital signal processing unit, dividing an input signal for each frequency width of a common divisor of a Nyquist frequency of a plurality of sub-digital-analog conversion units and a clock frequency of an analog multiplexer to generate N (N is a number of divisions) divided signals; by the digital signal processing unit, branching the generated N divided signals on a path and folding back the branched N divided signals on a frequency axis to obtain complex conjugation to generate N folded divided signals corresponding to the N divided signals; by the digital signal processing unit, receiving the N divided signals and the N folded divided signals as inputs, and generating N composite signals; by the digital signal processing unit, receiving the N composite signals as inputs and generating a plurality of digital signals corresponding to the respective sub-digital-analog conversion units; by the plurality of sub-digital-analog conversion units, converting the plurality of digital signals output from the digital signal processing unit into analog signals; and by an analog multiplexer, multiplexing the analog signals output from the plurality of sub-digital-analog conversion units to generate a broadband signal.

An aspect of the present invention is a computer program for causing a computer to function as the above-described signal generation device.

### Advantageous Effects of Invention

According to the present invention, it is possible to generate a high-speed signal by sufficiently utilizing a frequency domain.

### BRIEF DESCRIPTION OF DRAWINGS

FIG. 1 A block diagram illustrating a specific example of a functional configuration of a signal generation device according to the present invention.

FIG. 2 A diagram for describing an operation principle of the present invention.

FIG. 3 A diagram illustrating a configuration example of a conventional signal generation device.

FIG. 4 A diagram for describing a problem in the conventional signal generation device.

FIG. 5 A diagram for describing the problem in the conventional signal generation device.

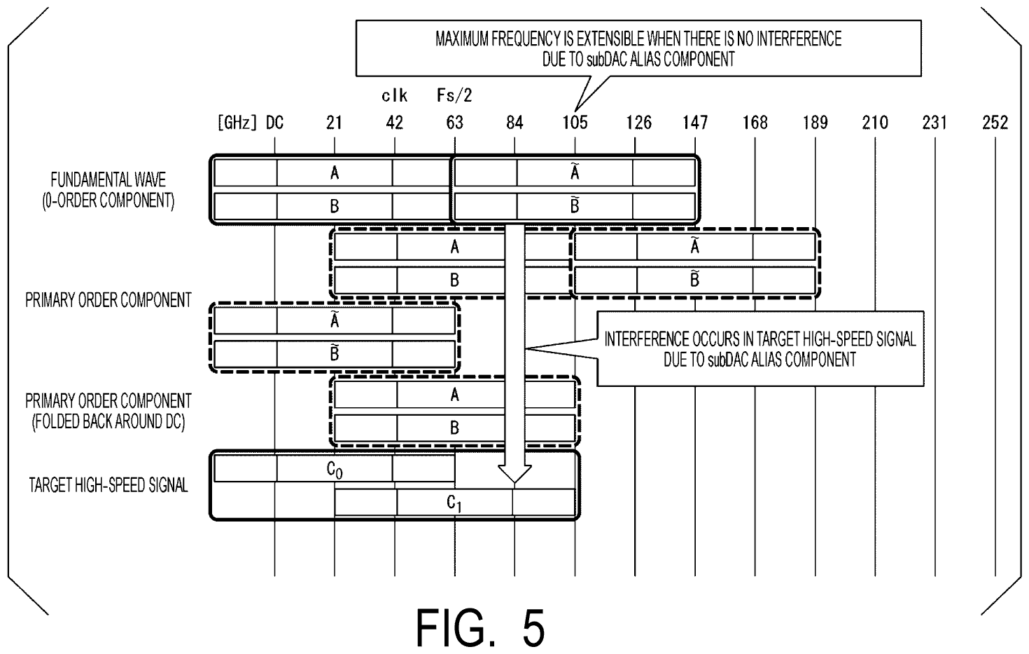

### DESCRIPTION OF EMBODIMENTS

Hereinafter, an embodiment of the present invention will be described with reference to the drawings.

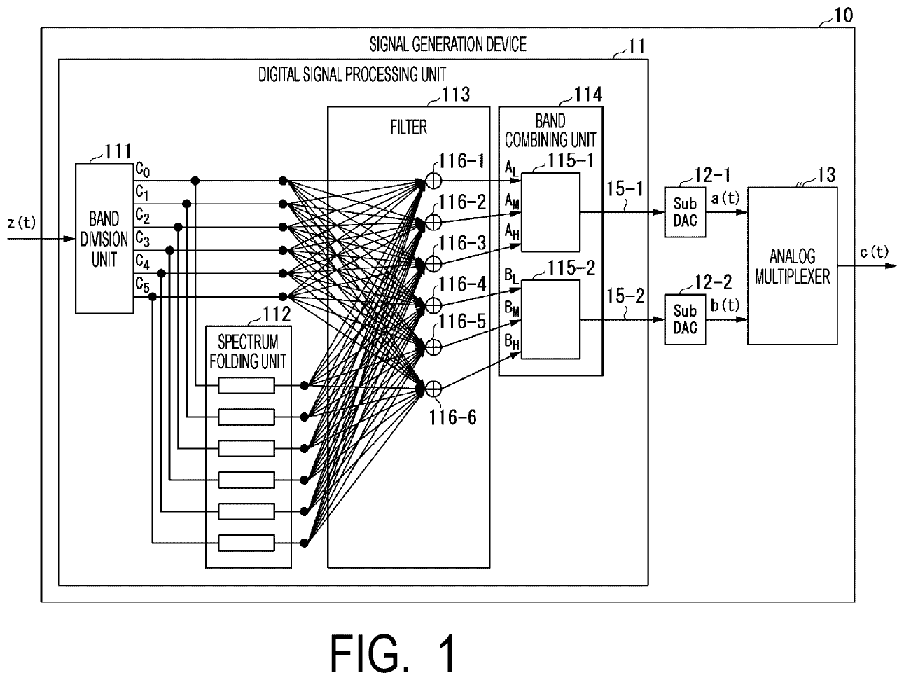

FIG. 1 is a block diagram illustrating a specific example of a functional configuration of a signal generation device 10 according to the present invention. The signal generation device 10 includes a digital signal processing unit 11, a plurality of SubDACs 12-1 and 12-2, and an analog multiplexer 13. Although the example in FIG. 1 illustrates a case where the number of SubDACs 12 is two, the present embodiment is applicable to a case where the number of SubDACs 12 is three or more.

The digital signal processing unit 11 performs digital signal processing for an input signal z(t) to generate a digital signal to be sent to each of the SubDACs 12-1 and 12-2 so as to obtain a desired analog signal as a final output signal c(t) according to characteristics of the analog multiplexer 13.

The SubDACs 12-1 and 12-2 convert a plurality of the digital signals output from the digital signal processing unit 11 into analog signals, respectively. For example, the SubDAC 12-1 converts the digital signal output from the digital signal processing unit 11 into an analog signal a(t), and the SubDAC 12-2 converts the digital signal output from the digital signal processing unit 11 into an analog signal b(t). In the present invention, the SubDACs 12-1 and 12-2 are driven at a sampling frequency at which a Nyquist frequency is smaller than an analog band of the SubDACs 12-1 and 12-2.

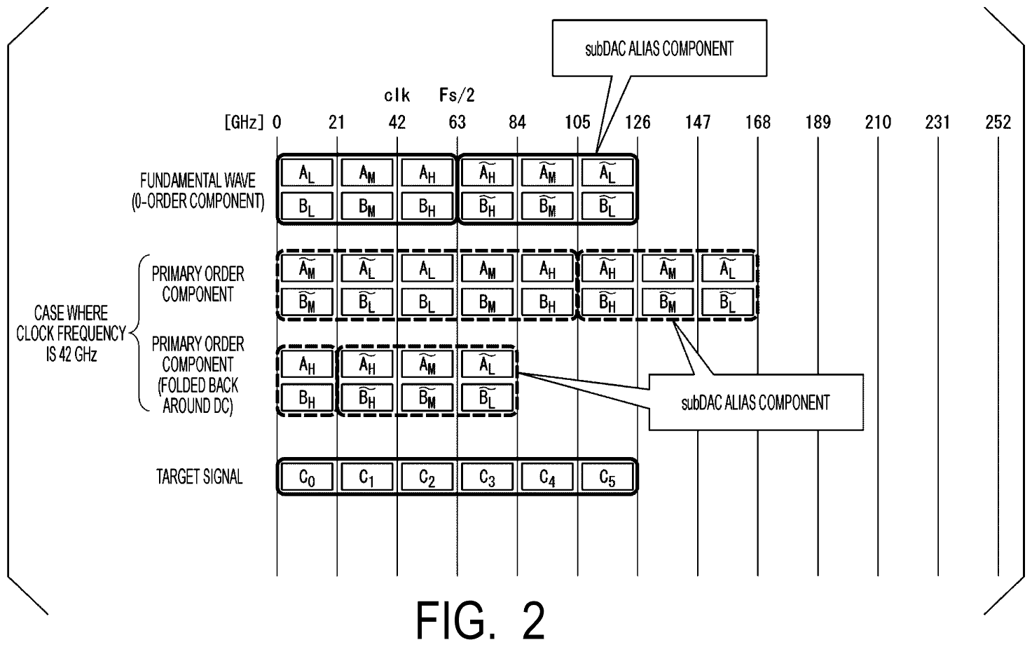

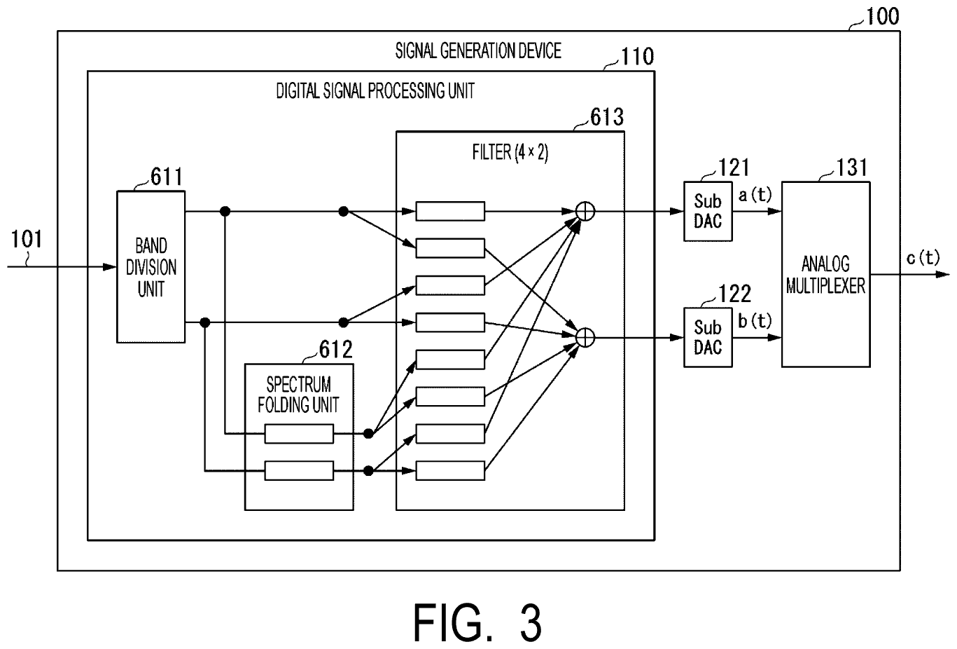

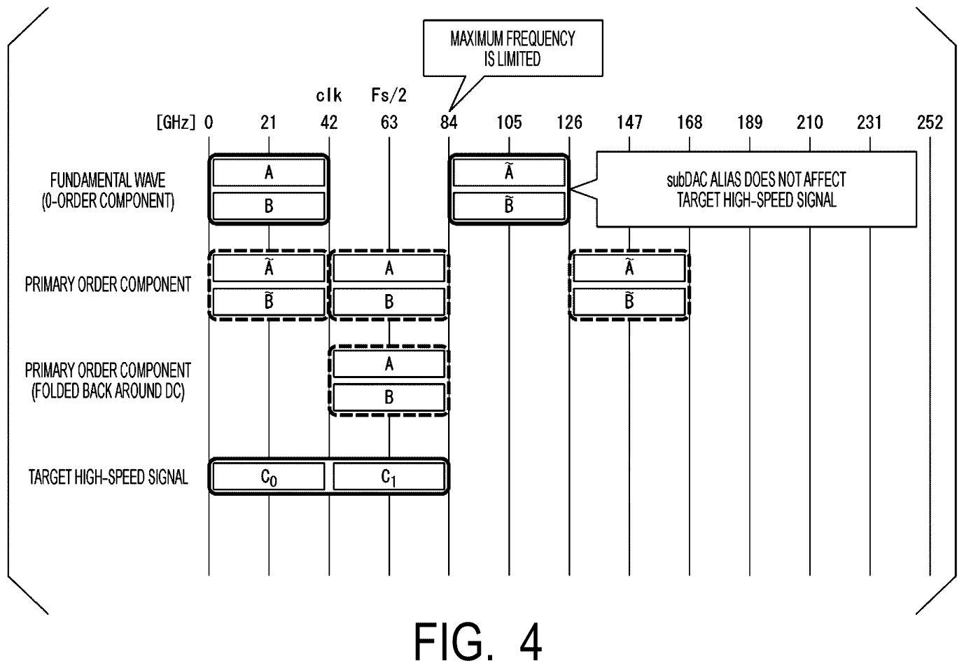

The analog multiplexer 13 multiplexes the analog signals a(t) and b(t) output from the SubDACs 12-1 and 12-2 to generate an output signal c(t) that is a broadband signal. Specific configuration examples of the analog multiplexer 13 include a configuration using an analog multiplexer illustrated in FIG. 2 of Patent Literature 1, a configuration using a mixer and a combiner illustrated in FIG. 3 of Patent Literature 1, and a configuration of an IQ modulator type including a mixer, a combiner, and a 90-degree phase shifter illustrated in FIG. 4 of Patent Literature 1. In the present example, the configuration using an analog multiplexer will be described as the configuration of the analog multiplexer 13. The analog multiplexer is a switch (selector) circuit that outputs each analog signal, which has been output from each SubDAC 12, while switching the signal at a clock frequency f_{clk} at a high speed.

The digital signal processing unit 11 includes a band division unit 111, a spectrum folding unit 112, a filter 113, and a band combining unit 114.

The band division unit 111 divides the input signal for each frequency width of a number represented by a common divisor of the Nyquist frequency of the SubDACs 12-1 and 12-2 and an input clock (clock frequency f_{clk}) of the analog multiplexer 13 to generate a plurality of divided signals. In the example illustrated in the present embodiment, it is assumed that a sampling frequency Fs of the SubDACs 12-1 and 12-2 is 126 GS/s, and the input clock of the analog multiplexer 13 is 42 GHz. Note that the sampling frequency of the SubDACs 12-1 and 12-2 and the input clock of the analog multiplexer 13 are not limited to the above example.

In the case of the above example, the Nyquist frequency of the SubDACs 12-1 and 12-2 is Fs/2=63. In this case, the common divisors of the Nyquist frequency of the SubDACs 12-1 and 12-2 and the input clock of the analog multiplexer 13 are “1” and “21”. For example, the band division unit 111 divides the input signal for each frequency width of 21 GHz that is the greatest common divisor to generate a plurality of divided signals (for example, in the example of FIG. 1, divided signals C₀, C₁, C₂, C₃, C₄, and C₅). In this manner, the band division unit 111 divides the input signal into N to generate N divided signals. N is a number (for example, 21) obtained by dividing the sampling frequency Fs (for example, 126) of the SubDACs 12-1 and 12-2 by the number represented by the common divisor. In the following description, the description will be given on the assumption of N=6. Note that, as an example, the configuration in which the band division unit 111 divides the input signal for each frequency width of the greatest common divisor has been described. However, in a case where there is a plurality of common divisors excluding “1”, the band division unit 111 may divide the input signal for each frequency width of another common divisor as long as the another common divisor is a common divisor other than “1”.

The spectrum folding unit 112 folds back the plurality of divided signals (for example, the divided signals C₀, C₁, C₂, C₃, C₄, and C₅) generated by the band division unit 111 around a direct current (DC) on a frequency axis to obtain complex conjugation to generate a plurality of folded divided signals (for example, divided signals ˜C₀, ˜C₁, ˜C₂, ˜C₃, ˜C₄, and ˜C₅) corresponding to the plurality of divided signals. Note that ˜ is added on the letter (for example, C).

The filter 113 receives the plurality of divided signals C₀, C₁, C₂, C₃, C₄, and C₅ generated by the band division unit 111 and the plurality of folded divided signals ˜C₀, ˜C₁, ˜C₂, ˜C₃, ˜C₄, and ˜C₅ generated by the spectrum folding unit 112 as inputs, and generates a plurality of composite signals A_{L}, A_{M}, A_{H}, B_{L}, B_{M}, and B_{H} to be output to the SubDACs 12-1 and 12-2. The filter 113 is a 2N×N (for example, 12×6) filter. For example, the filter 113 illustrated in FIG. 1 includes 2N×N convolution arithmetic operation units (not illustrated) and N addition units 116-1 to 116-N (addition units 116-1 to 116-6).

The 2N×N convolution arithmetic operation units multiply the plurality of input divided signals or the plurality of folded divided signals by independently settable response functions. In FIG. 1, illustration of the 2N×N convolution arithmetic operation units is omitted for convenience of the drawing, but the plurality of divided signals and the plurality of folded divided signals input to the filter 113 are multiplied by the response function by the 2N×N convolution arithmetic operation units, and then input to all the addition units 116-1 to 116 N (addition units 116-1 to 116-6).

In a case where N=6, the filter 113 is configured as a 12-input 6-output filter, and includes seventy-two convolution arithmetic operation units and six addition units 116-1 to 116-6. Each of the plurality of divided signals and the plurality of folded divided signals input to the filter 113 is branched into N paths, and the response function is multiplied by the N convolution arithmetic operation units provided in the N paths.

For example, when the divided signal C₀ is input to the filter 113, the divided signal C₀ is branched into six paths, and the response function is multiplied by the first to sixth convolution arithmetic operation units provided in the six paths. Similarly, when the divided signal C₁ is input to the filter 113, the divided signal C₁ is branched into six paths, and the response function is multiplied by the seventh to twelfth convolution arithmetic operation units provided in the six paths. Similarly, when the divided signal C₂ is input to the filter 113, the divided signal C₂ is branched into six paths, and the response function is multiplied by the thirteenth to eighteenth convolution arithmetic operation units provided in the six paths. Similarly, when the divided signal C₃ is input to the filter 113, the divided signal C₃ is branched into six paths, and the response function is multiplied by the nineteenth to twenty-fourth convolution arithmetic operation units provided in the six paths. Similarly, when the divided signal C₄ is input to the filter 113, the divided signal C₄ is branched into six paths, and the response function is multiplied by the twenty-fifth to thirtieth convolution arithmetic operation units provided in the six paths. Similarly, when the divided signal C₅ is input to the filter 113, the divided signal C₅ is branched into six paths, and the response function is multiplied by the thirty-first to thirty-sixth convolution arithmetic operation units provided in the six paths.

When the folded divided signal ˜C₀ is input to the filter 113, the folded divided signal ˜C₀ is branched into six paths, and the response function is multiplied by the thirty-seventh to forty-second convolution arithmetic operation units provided in the six paths. Similarly, when the folded divided signal ˜C₁ is input to the filter 113, the folded divided signal ˜C₁ is branched into six paths, and the response function is multiplied by the forty-third to forty-eighth convolution arithmetic operation units provided in the six paths. Similarly, when the folded divided signal ˜C₂ is input to the filter 113, the folded divided signal ˜C₂ is branched into six paths, and the response function is multiplied by the forty-ninth to fifty-fourth convolution arithmetic operation units provided in the six paths. Similarly, when the folded divided signal ˜C₃ is input to the filter 113, the folded divided signal ˜C₃ is branched into six paths, and the response function is multiplied by the fifty-fifth to sixtieth convolution arithmetic operation units provided in the six paths. Similarly, when the folded divided signal ˜C₄ is input to the filter 113, the folded divided signal ˜C₄ is branched into six paths, and the response function is multiplied by the sixty-first to sixty-sixth convolution arithmetic operation units provided in the six paths. Similarly, when the folded divided signal ˜C₅ is input to the filter 113, the folded divided signal ˜C₅ is branched into six paths, and the response function is multiplied by the sixty-seventh to seventy-second convolution arithmetic operation units provided in the six paths.

FIG. 1 illustrates the configuration in which the divided signal C₀ is multiplied by the response function and input to all the addition units 116-1 to 116-6), but other divided signals (for example, the divided signals C₁, C₂, C₃, C₄, and C₅) and the plurality of folded divided signals (for example, divided signals ˜C₀, ˜C₁, ˜C₂, ˜C₃, ˜C₄, and ˜C₅) are similarly multiplied by the response function by any one of the 2N×N convolution arithmetic operation units and input to all the addition units 116-1 to 116-6.

To give description on the basis of the above-described case of N=6, the addition unit 116-1 receives, as inputs: the divided signal C₀ multiplied by the response function by the first convolution arithmetic operation unit; the divided signal C₁ multiplied by the response function by the seventh convolution arithmetic operation unit; the divided signal C₂ multiplied by the response function by the thirteenth convolution arithmetic operation unit; the divided signal C₃ multiplied by the response function by the nineteenth convolution arithmetic operation unit; the divided signal C₄ multiplied by the response function by the twenty-fifth convolution arithmetic operation unit; the divided signal C₅ multiplied by the response function by the thirty-first convolution arithmetic operation unit; the folded divided signal ˜C₀ multiplied by the response function by the thirty-seventh convolution arithmetic operation unit; and the folded divided signal ˜C₁ multiplied by the response function by the forty-third convolution arithmetic operation unit, the folded divided signal ˜C₂ multiplied by the response function by the forty-ninth convolution arithmetic operation unit; the folded divided signal ˜C₃ multiplied by the response function by the fifty-fifth convolution arithmetic operation unit; the folded divided signal ˜C₄ multiplied by the response function by the sixty-first convolution arithmetic operation unit; and the folded divided signal ˜C₅ multiplied by the response function by the sixty-seventh convolution arithmetic operation unit. In this manner, N divided signals and N folded divided signals are input to one addition unit 116.

The addition units 116-1 to 116-6 add the divided signal and the folded divided signal multiplied by the response function by the convolution arithmetic operation unit to generate the composite signal. For example, the addition unit 116-1 adds N divided signals and N folded divided signals multiplied by the response function by the (6k+1)th (k is 0 to (2N−1)) convolution arithmetic operation unit to generate a composite signal A_{L}. Similarly, the addition unit 116-2 adds N divided signals and N folded divided signals multiplied by the response function by the (6k+2)th convolution arithmetic operation unit to generate a composite signal A_{M}. Similarly, the addition unit 116-3 adds N divided signals and N folded divided signals multiplied by the response function by the (6k+3)th convolution arithmetic operation unit to generate a composite signal A_{H}. Similarly, the addition unit 116-6 adds N divided signals and N folded divided signals multiplied by the response function by the (6k+6)th convolution arithmetic operation unit to generate a composite signal B_{L}. Similarly, the addition unit 116-5 adds N divided signals and N folded divided signals multiplied by the response function by the (6k+5)th convolution arithmetic operation unit to generate a composite signal B_{M}. Similarly, the addition unit 116-6 adds N divided signals and N folded divided signals multiplied by the response function by the (6k+6)th convolution arithmetic operation unit to generate a composite signal Bn.

As described above, the filter 113 is a filter that obtains a composite signal by multiplying a plurality of divided signals and a plurality of folded divided signals by the independently settable response function and then superimposing the plurality of signals.

Here, the response function used for convolution by the 2N×N convolution arithmetic operation units is calculated as a coefficient that approaches the input signal z(t) when the output signal c(t) is output via the analog multiplexer 13.

The band combining unit 114 uses the plurality of composite signals A_{L}, A_{M}, A_{H}, B_{L}, B_{M}, and B_{H} output from the filter 113 as inputs, and generates a plurality of digital signals respectively corresponding to the SubDACs 12-1 and 12-2. The band combining unit 114 includes a first band combining unit 115-1 and a second band combining unit 115-2. The first band combining unit 115-1 combines bands of the composite signals A_{L}, A_{M}, and A_{H} respectively generated by the plurality of addition units 116-1 to 116-3 to generate a first combined signal 15-1 to be output to the SubDAC 12-1. The second band combining unit 115-2 combines bands of the composite signals B_{L}, B_{M}, and B_{H} respectively generated by the plurality of addition units 116-4 to 116-6 to generate a second combined signal 15-2 to be output to the SubDAC 12-2.

FIG. 2 is a diagram for describing an operation principle of the present invention. FIG. 2 illustrates an example of a case where the sampling frequency of the SubDAC 12 is 126 GS/s and the clock frequency of the analog multiplexer 13 is 42 GHz. As illustrated in FIG. 2, the alias component occurs line-symmetrically about 63 GHz that is the Nyquist frequency. A_{L}, A_{M}, A_{H}, B_{L}, B_{M}, and B_{H} represent the composite signals, and ˜A_{L}, ˜A_{M}, ˜A_{H}, ˜B_{L}, ˜B_{M}, and ˜B_{H} (˜ is added on A and B) represent signals having complex conjugation of the composite signal in FIG. 2. “L”, “M”, and “H”, which are subscripts of “A” and “B”, represent Low, High, and Middle, respectively.

As described above, by considering the band of 21 GHz×6 segments, it is possible to digitally cancel the alias component by a matrix operation of 12×12 including the folded divided signal and obtain a desired signal. As a result, operation as a DAC of 252 GS/s becomes possible (an upper limit is 210 GS/s in the conventional configuration under the condition without aliasing).

By solving simultaneous equations from the relationship illustrated in FIG. 2 and obtaining A_{L}, A_{M}, A_{H}, B_{L}, B_{M}, and B_{H}, it is possible to calculate desired C₀, C₁, C₂, C₃, C₄, C₅, and C₆ even in the case where an alias signal is generated from the subDAC 12.

According to the signal generation device 10 configured as described above, the digital signal processing unit 11 divides the input signal for each frequency width of the common divisor of the Nyquist frequency of the plurality of SubDACs 12 and the clock frequency of the analog multiplexer 13 to generate the plurality of divided signals, has the plurality of divided signals branched on the paths and folds back the plurality of branched divided signals on the frequency axis to obtain complex conjugation to generate the plurality of folded divided signals corresponding to the plurality of divided signals, receives the plurality of divided signals and the plurality of folded divided signals as inputs to generate the plurality of composite signals, and receives the plurality of composite signals as inputs to generate the plurality of digital signals corresponding to the respective SubDACs 12.

As described above, the signal generation device 10 divides the input signal into the subbands having the band width of the common divisor of the Nyquist frequency (half the sampling frequency) of the SubDAC 12 and the clock frequency input to the analog multiplexer 13, pre-equalizes the subband signal and its complex conjugate signal by the MIMO processing, and allocates the equalized subband signal to each band of the SubDAC 12, thereby enabling compensation of interference by the alias image, digitally canceling the alias component by matrix operation including the inverted signal, and obtaining a desired signal. Therefore, it is possible to generate a high-speed signal by effectively utilizing the frequency band of the SubDAC 12.

Some functional units of the signal generation device 10 in the above-described embodiment may be implemented by a computer. In this case, a program for implementing this function may be recorded in a computer-readable recording medium, and the program recorded in the recording medium may be read and executed by a computer system to implement the function. Note that, the “computer system” herein includes an OS and hardware such as peripheral devices.

The “computer-readable recording medium” refers to a portable medium such as a flexible disk, a magneto-optical disk, a read only memory (ROM), or a CD-ROM, or a storage device such as a hard disk included in a computer system, for example. Moreover, the “computer-readable recording medium” may include a medium that dynamically holds the program for a short time, such as a communication line in a case where the program is transmitted via a network such as the Internet or a communication line such as a telephone line, and a medium that holds the program for a certain period of time, such as a volatile memory inside a computer system serving as a server or a client in that case. The above-described program may be for implementing some of the functions described above, may be implemented by a combination of the functions described above and a program already recorded in a computer system, or may be implemented with a programmable logic device such as a field-programmable gate array (FPGA).

Although the embodiments of the present invention have been described in detail with reference to the drawings, the specific configuration is not limited to the embodiments, and includes design and the like without departing from the gist of the present invention.

### INDUSTRIAL APPLICABILITY

The present invention can be applied to a technique for generating a high-speed signal.

### REFERENCE SIGNS LIST

10 Signal generation device
11 Digital signal processing unit
12-1, 12-2 SubDAC
13 Analog multiplexer
111 Band division unit
112 Spectrum folding unit
113 Filter
114 Band combining unit
115-1 First band combining unit
115-2 Second band combining unit

1. A signal generation device comprising:
a digital signal processor;
a plurality of sub-digital-analog converters configured to respectively convert a plurality of digital signals output from the digital signal processor into analog signals; and
an analog multiplexer configured to multiplex the analog signals output from the plurality of sub-digital-analog converters to generate a broadband signal,
wherein the digital signal processor includes
a band divider configured to divide an input signal for each frequency width of a common divisor of a Nyquist frequency of the plurality of sub-digital-analog converters and a clock frequency of the analog multiplexer to generate N (N is a number of divisions) divided signals,
a spectrum folder configured to have the N divided signals generated by the band divider branched on a path, and folds back the branched N divided signals on a frequency axis to obtain complex conjugation to generate N folded divided signals corresponding to the N divided signals,
a filter configured to receive the N divided signals and the N folded divided signals as inputs and generates N composite signals, and
a band combiner configured to receive the N composite signals as inputs and generates a plurality of digital signals corresponding to the respective sub-digital-analog-converters.

2. The signal generation device according to claim 1, wherein
the band combiner includes a plurality of band combiners configured to generate the digital signal for each of the sub-digital-analog-converters, and
each of the band combiners generates the digital signal for each of the sub-digital-analog converters by combining bands of the composite signals that are different from each other.

3. The signal generation device according to claim 1, wherein
the filter includes 2N×N convolution arithmetic operators and N adders,
the 2N×N convolution arithmetic operators receive the N divided signals and the N folded divided signals as inputs, and multiply the input N divided signals and the input N folded divided signals by a response function, and
the N adders output N composite signals obtained by adding the N divided signals multiplied by the response function and the N folded divided signals multiplied by the response function to the band combiner.

4. The signal generation device according to claim 1, wherein
the Nyquist frequency of the plurality of sub-digital-analog converters is larger than the clock frequency of the analog multiplexer.

5. A signal generation method comprising:
by a digital signal processor, dividing an input signal for each frequency width of a common divisor of a Nyquist frequency of a plurality of sub-digital-analog converters and a clock frequency of an analog multiplexer to generate N (N is a number of divisions) divided signals;
by the digital signal processor, branching the generated N divided signals on a path and folding back the branched N divided signals on a frequency axis to obtain complex conjugation to generate N folded divided signals corresponding to the N divided signals;
by the digital signal processor, receiving the N divided signals and the N folded divided signals as inputs, and generating N composite signals;
by the digital signal processor, receiving the N composite signals as inputs and generating a plurality of digital signals corresponding to the respective sub-digital-analog converters;
by the plurality of sub-digital-analog converters, converting the plurality of digital signals output from the digital signal processor into analog signals; and
by an analog multiplexer, multiplexing the analog signals output from the plurality of sub-digital-analog converters to generate a broadband signal.

6. A non-transitory storage medium that stores a program for making a computer perform processes, the processes comprising:
dividing an input signal for each frequency width of a common divisor of a Nyquist frequency of a plurality of sub-digital-analog converters and a clock frequency of an analog multiplexer to generate N (N is a number of divisions) divided signals;
branching the generated N divided signals on a path and folding back the branched N divided signals on a frequency axis to obtain complex conjugation to generate N folded divided signals corresponding to the N divided signals;
receiving the N divided signals and the N folded divided signals as inputs, and generating N composite signals;
receiving the N composite signals as inputs and generating a plurality of digital signals corresponding to the respective sub-digital-analog converters;
converting the plurality of digital signals into analog signals; and
multiplexing the analog signals to generate a broadband signal.
